(19) United States
(12) Patent Application Publication
(10) Pub. No.: US 2024/0098848 A1
(43) Pub. Date: Mar. 21, 2024

(54) Control Device and Electric Heating Device Comprising the Same

(71) Applicant: Eberspächer catem GmbH & Co. KG, Herxheim (DE)

(72) Inventors: Simon Georg Kräck, Karlsruhe (DE); Timo Kröner, Rülzheim (DE)

(21) Appl. No.: 18/368,299

(22) Filed: Sep. 14, 2023

(30) Foreign Application Priority Data
Sep. 15, 2022 (DE) 10 2022 123 572.6

(51) Int. Cl. H05B 3/06; H05K 7/20

(52) U.S. Cl. CPC H05B 3/06; H05K 7/2049; H05B 2203/02; H05B 2203/023

(57) ABSTRACT

A control device and electric heating device having such a control device are disclosed. The control device has a control housing which surrounds a printed circuit board, which has a partition wall provided with a cooling element, and which accommodates at least one power switch that makes contact with the printed circuit board and that is applied in a heat-conducting manner against the cooling element via a hold-down device. The power switch and the hold-down device are realized in a pre-assembled module connected to the cooling element.

### BACKGROUND OF THE INVENTION

### 1. Field of the Invention

The present invention relates to a control device, in particular for an electric heating device with a PTC element as an auxiliary heater in a motor vehicle.

### 2. Background of Related Art

Control devices, in particular for electric heating devices with a ceramic PTC element for heating motor vehicles, are sufficiently described in the prior art, for example in EP 1 872 986 A1 or EP 2 337 425 A1. A control device in such an electric heating device usually has a control housing which surrounds the control components and is provided with plug-in connections for connecting control signals and/or the power current to be controlled. The previously described examples as well as the electric heating device from EP 3 334 242 A1 realize a concept in which the control device is provided integrally with the power section. The control device has at least one power switch, which emits power loss during operation. This is usually supplied to the medium to be heated. Accordingly, the power switch is not only provided with a cooling element which dissipates the power loss and accordingly counteracts overheating of the power switch. The cooling element is rather thermally coupled with the fluid to be heated. For this purpose, the cooling element can be provided in a heating chamber, which is separated from the accommodation chamber of the control housing by a partition wall, in which the part of the cooling element in contact with the power switch is accommodated. Usually, a partition wall is provided between the accommodation chamber of the control housing and the heating chamber, which delimits both the heating chamber and the accommodation chamber of the control housing. This partition wall can itself form the cooling element or have a separate cooling element projecting through it. The cooling element forms a cooling surface against which the power switch is applied in a heat-conducting manner. In this context, the control housing can also accommodate contact zones of PTC heating assemblies, which usually protrude into the heating chamber and comprise at least one PTC element. Thus, in the prior art, the interior of the control housing is also referred to as connection chamber, since the contact zones in this chamber are electrically connected.

The previously mentioned features also apply to the realization of the control device according to the invention in an electric heating device with a ceramic PTC element as auxiliary heater.

Control devices in automotive engineering are subject to the conditions prevailing there. The control components inside the control device are subjected to considerable vibration. It goes without saying that the control housing must be as tight as possible so that neither dust nor moisture can penetrate the control housing. However, the installed components not only have to be provided with vibration resistance. The aim is to achieve a construction that provides the desired functionality with as few components as possible. In this context, the components should be easy to manufacture, scalable and insensitive to handle during production. The components must remain functional throughout the service life of the vehicle and despite the above-mentioned conditions.

The present invention is, in particular, related to the problem of applying the power switch in a heat-conducting manner under pretension against a cooling element. There has already been no lack of proposals for this in the prior art.

For example, EP 1 395 098 A1 discloses a control device of an electric heating device with a PTC element, in which a heat sink is directly applied in a heat-conducting manner against a power switch mounted on a printed circuit board and protrudes from the printed circuit board on the side opposite the power switch. The cooling element and the power switch are embraced by a C-shaped spring claw which holds the two components abutted against each other under pretension.

In the construction principle known from U.S. Pat. No. 5,812,375, the power switch is applied against the surface of a heat sink with the interposition of an electrically insulating film, which engages in an accommodation opening of a printed circuit board, to the strip conductors of which the power switch is electrically connected. On the side opposite the heat sink, an elastomeric component with a U-shaped cross-section is applied against the power switch and is supported on a housing cover of the control housing. For this purpose, the housing cover has a protrusion which is embraced by the in cross-section U-shaped pretensioner.

DE 100 34 572 A1 discloses a control device for an auxiliary holder of a motor vehicle, in which an at least partially elastic press protrusion protrudes from a housing cover and is provided opposite a cooling element which is coupled to the heating chamber in a heat-conducting manner A power switch is arranged between the pressing projection and the cooling element, which is applied against the cooling element with the interposition of a possibly elastic, heat-conducting, however electrically insulating film.

For vibration-free support of the printed circuit board on a housing bottom of a control housing, DE 196 00 619 A1 proposes a pretensioner acting on the power switch in the form of an elastomer strip, which presses the power switch and intermediate layer of the printed circuit board against an outer edge of the control housing.

The solutions known from the prior art still leave something to be desired. The previously known solution from DE 196 00 619 A1 is not always applicable in practice, since this solution requires a raised edge area against which the printed circuit board is applied. The edge area of the control device is not always located below the edge area of the control housing in the case of an electric heating device with a structural unit comprising a control section and a power section.

Furthermore, a certain height must sometimes be bridged between the power switch and a housing cover, so that the elastomer strip known from DE 196 00 619 A1 is unsuitable for applying the power switch under pretension against a cooling element.

In view of this, EP 2 466 989 A1, which originates from the present applicant, proposes a supporting structure which is provided between the housing cover and a printed circuit board and supports an elastic hold-down device made of a compressive plastic, which penetrates the printed circuit board and is applied against a power switch in order to apply the latter under pretension against the cooling surface of a heat sink which is connected to the heating chamber in a heat-conducting manner.

### SUMMARY

The present invention aims to provide a control device that allows good heat transfer between the power switch and the cooling surface and can be easily and inexpensively manufactured.

According to the present invention, a control device includes a printed circuit board and a control housing. The control housing surrounds the printed circuit board, has a partition wall provided with a cooling element, and accommodates at least one power switch. The power switch makes contact with the printed circuit board and is applied in a heat-conducting manner against the cooling element via a hold-down device. The power switch and the hold-down device are realized in a pre-assembled module connected to the cooling element.

In this context, the hold-down device, as such, may form accommodations for one or more power switches. The power switches are thereby held in a predetermined arrangement in at least one direction transverse to the printed circuit board.

The hold-down may be formed from a plastic material. The hold-down device may be formed of elastic material, such as an elastic or soft-elastic plastic, and/or may support a spring device, which can be formed, for example, by a biasing element made of this elastic or soft-elastic plastic material. The hold-down device may generate a biasing force biasing the power switch against a cooling surface of the heat sink or supports such an elastic biasing force. The hold-down device is directly connected to the control housing, such as being screwed thereto.

The module allows the power switch(es) to be handled uniformly and mounted in the control device. As a result, cost-effective manufacturing can be realized. This applies in particular if several power switches are installed in the control device and are accommodated in the module.

With regard to the best possible heat extraction of the heat generated by the power switches, the control device may have at least a spring device. Usually, one single spring device is assigned to a corresponding power switch, so that the power switch is held pretensioned by this spring device. The pretension is such that the power switch is applied under pretension against the cooling surface. In this further development, the spring device is accommodated in the module. Thus, by handling and assembling the module, the power switch can be applied under pretension against the cooling surface.

The spring device may be held on the hold-down device by at least one form-fit connection acting transversely to the direction of action of its spring force. For this purpose, the hold-down device can have a pin extending essentially at right angles to the main extension of the printed circuit board, which is positively embraced by the spring device. However, any other type of positive connection is conceivable. However, a pin connection has proven to be advantageous if the spring device is made of a plastic, in particular a silicone, and is realized as a hollow body so that the pin can engage in the hollow body and hold it positively. A spring device made of a silicone is also suitable because of the good heat resistance of the plastic. Furthermore, a silicone spring provides good elastic and electrically insulating support for the power switch.

In accordance with a possible further development of the present invention, the power switch is held movably in the module while varying a pretension caused by the spring device. Thus, the module has a support which prevents the power switch from being pressed out of the module due to the acting spring force. On the other hand, the power switch can be moved away from the support by increasing the spring force of the spring device. The configuration is usually chosen so that the power switch flatly abuts the cooling surface even with increasing compression of the spring. In this way, the power switch remains within the module, but within certain limits it can avoid a pretensioning force against the cooling surface by moving within the module. This allows the preloading force to act unhindered on the power switch.

According to a possible further development of the present invention, the module has a positioning frame. This forms at least one accommodation for a power switch. In the accommodation, the power switch is usually positively held at least in a direction transverse to the plane of the printed circuit board. For the reasons mentioned above, the power switch is regularly movable transversely to this extension direction of the printed circuit board within the positioning frame.

With regard to cost-effective manufacturing, the positioning frame and the hold-down device are usually made of plastic. Both components are clipped together, typically under inclusion of the at least one power switch and—if present—the spring device. For assembling, the power switch is received in the positioning frame. The positioning frame thus equipped with the power switch(es) is then connected to the hold-down device by clipping. This may be previously provided with the spring device assigned to the power switch. The connection between the positioning frame and the hold-down device can result in a substantially rigid connection between the two components. Equally well, the latching connection made by clipping may be such that the positioning frame is also movable in a direction perpendicular to the cooling surface, which may favor the flat abutment of the power switch against the cooling surface.

The positioning frame usually has an opening surrounding the cooling surface. This is dimensioned so that the cooling surface can usually engage in the opening and be contacted with the power switch in a heat-conducting manner. The opening is bounded by a support for the power switch. The power switch is placed on this support in the course of assembly. This support rests the power switch against it when the spring device acts against the power switch after the positioning frame and the hold-down device have been joined. The support thus represents a mating surface in the course of assembly, against which the power switch is pressed by the spring device.

According to a possible further configuration of the present invention, the positioning frame has a window which is penetrated by at least one contact pin of the power switch. This window is bounded at the top by the hold-down device. Before joining the hold-down device and the positioning frame, the power switch can accordingly be inserted into the positioning frame, with the contact pin or pins being introduced into the window from above through the opening of the positioning frame. This facilitates the insertion of the power switch(es) into the positioning frame.

The control device may have form-fit segments on the side of the cooling element, which cooperate with form-fit mating segments of the printed circuit board for positioning the module transversely to the plane of the printed circuit board. These form-fit mating segments may be implemented on the hold-down device. The interaction of the form-fit segments with the form-fit mating segments results in appropriate pre-positioning of the module relative to the cooling element during assembly, so that the power switch is securely applied against the cooling surface.

A power switch according to the present invention can, for example, be formed by a MOSFET or an IGBT. The abutment against the cooling surface can be made by interposing an electrically insulating film, for example a polyimide film, in order to electrically decouple the cooling surface from the power switch, but nevertheless allow good heat conduction from the power switch to the cooling surface. Alternatively, a ceramic plate may be provided between the cooling surface and the power switch.

With regard to an easy application of the pretensioning force for the pretensioned application of the power switch against the cooling surface, the assembly is usually connected to the connection housing in a direction perpendicular to the extension of the printed circuit board. This may be done by screws, which may be retained within the form-fit segments. By tightening the screws, the pretensioning force of the spring device is also effected or increased, and in any case the power switch(es) is/are applied under pretension against the cooling element.

According to its parallel aspect, the present invention proposes an electric heating device having the features of claim 10. This electric heating device has, in the manner already known from EP 2 466 989 A1 and a U.S. counterpart US2012008764, a partition wall between a control housing and a heater housing. Both documents are incorporated by reference. This partition wall usually forms both a closure of a heating chamber formed by the heater housing and a closure of the control housing. At least one PTC heating assembly protrudes from the partition wall into a heating chamber of the heater housing as a heating fin. The PTC heating assembly can be accommodated in the partition wall with plug-in contacts or otherwise positioned and fixed relative thereto. The PTC heating assembly has at least one PTC element and strip conductors electrically conductively connected to it for energizing it with different polarity. The strip conductors are electrically connected in the control housing. For this purpose, they protrude into the control housing and can be plug-in contacted with the printed circuit board, which also carries the power switch, or another printed circuit board, which is provided for grouping heating circuits comprising several PTC heating assemblies. A heat sink is exposed in the heating chamber and is heat-conductively connected to a cooling surface provided in the connection chamber. The power switch is applied against this cooling surface, so that the power dissipated by the power switch can also be used to heat the fluid to be heated in the heating device. This fluid can be a liquid fluid or a gaseous fluid, in particular air.

### BRIEF DESCRIPTION OF THE DRAWINGS

This previously mentioned electric heating device has a control device according to one of the preceding claims.

Further details and advantages of the present invention will be apparent from the following description in conjunction with the drawing. Therein:

FIG. 1 shows a perspective exploded view of an embodiment of an electric heating device;

FIG. 2 shows a longitudinal sectional view of a PTC heating assembly of the heating device according to FIG. 1;

FIG. 3 shows a perspective side view of a module above the printed circuit board and the cooling element;

FIG. 4 shows a longitudinal sectional view of a module after assembly;

FIG. 5 shows a cross-sectional view of the module according to FIG. 3;

FIG. 6 shows a perspective side view of an alignment element before assembly;

FIG. 7 shows a perspective side view of an alignment element after assembly;

FIG. 8 shows an enlarged detail of FIG. 5;

FIG. 9 shows a top view of the illustration according to FIG. 8.

### DETAILED DESCRIPTION

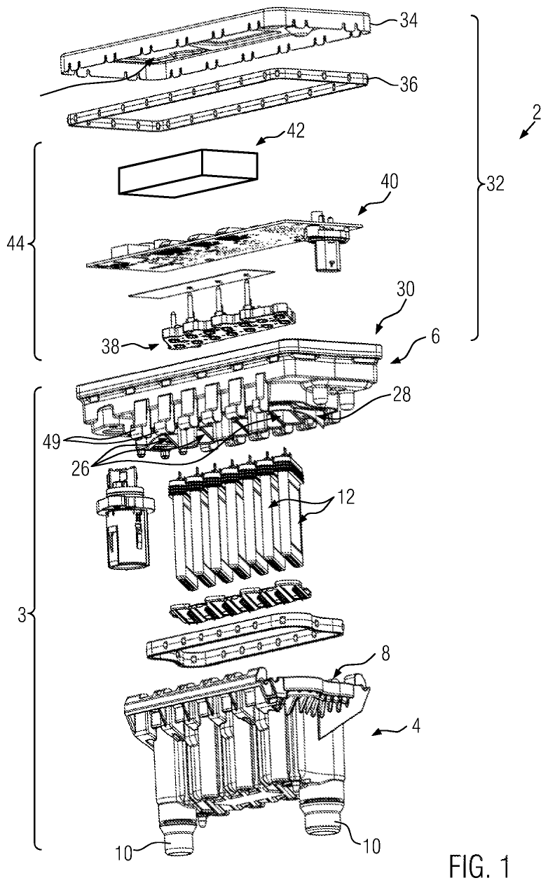

FIG. 1 shows an embodiment of an electric heating device 2 with a multi-part heater housing 3 comprising a housing lower part 4 formed of plastic and a housing upper part 6 integrally formed of metal by die casting.

The housing lower part 4 is trough-shaped, encloses a heating chamber 8 and forms openings to inlet and outlet ports 10 which communicate with the heating chamber 8. These inlet and outlet ports 10 are integrally formed with the housing lower part 4 by injection molding. A plurality of PTC heating assemblies 12 are shown between the housing upper part 6 and the housing lower part 4.

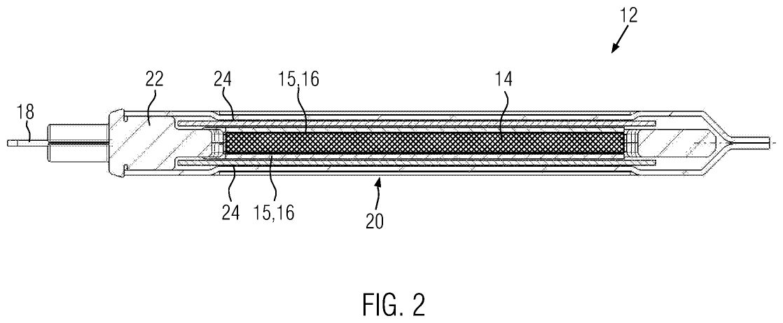

As illustrated in FIG. 2, these PTC heating assemblies 12 each have at least one PTC element 14 against which conductor elements 15 in form contact sheets 16 abut, which form contact tongues 18 that extend beyond a metal housing 20. The PTC element 14 is accommodated in a frame 22 and between the contact sheets 16. Between each of the metallic housing 20 and the contact sheets 16 an insulating layer 24 is provided.

The PTC heating assemblies 12 are held in plug-in contact in accommodations 26 provided for this purpose in a partition wall 28 of the housing upper part 6. Details of this configuration are described in EP 3 334 242 A1 and counterpart U.S. Pat. No. 10,724,763, which originates from the applicant and the subject matter of which are hereby incorporated by reference.

On the side of the partition wall 28 opposite the PTC heating assemblies 12, a connection chamber 30 is formed, which is surrounded by a control housing 32 comprising a control housing cover 34, which is connected to the housing upper part 6 in a sealed manner via a seal 36. A first printed circuit board 38 is located in the connection chamber 30, which accommodates the contact tongues 18 and groups the individual PTC heating assemblies 12 into heating circuits

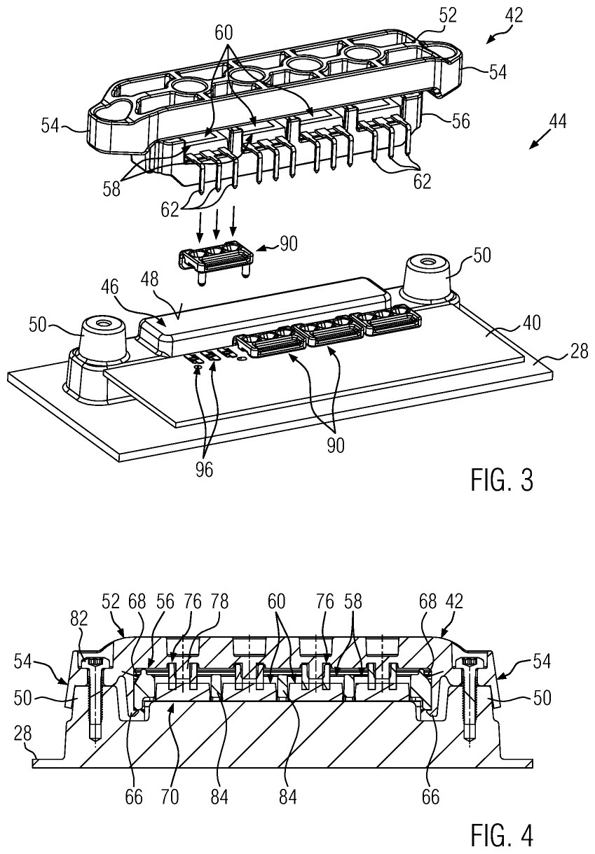

In the control housing 32, a second printed circuit board characterized by reference sign 40 is provided, which is equipped with electronic components not shown in detail. Reference sign 42 characterizes a module shown in more detail in further FIG. 3 et seq. which is part of the control device characterized by reference sign 44 in FIG. 1.

Next to the module 42, FIG. 3 schematically shows the partition wall 28 from which a cooling element 46 projects in the direction of the connection chamber 30. This cooling element 46 forms a flat cooling surface 48. The cooling elements 46 are extended into the heating chamber 8 and form heat sinks 49 there. In extension of the cooling surface 48 and adjacent thereto, the housing upper part 6 also forms form-fit segments 50 on the side of the cooling element, which also protrude as slightly conical projections from the partition wall 28 presently schematically shown flatly.

The module 42 includes a hold-down device 52 that is formed as an elongated plastic component and forms form-fit mating segments 54 at its respective ends, which can positively cooperate with the form-fit segments 50 to position the hold-down device 52 relative to the housing upper part 6 and thus the control housing 32.

With reference sign 56, a positioning frame is characterized that forms a plurality of accommodations 58 for power switches 60. Each power switch 60 has three contact pins, characterized by reference sign 62, that are bent about 90 degrees approximately centrally and have a contact-side section 64 that extends substantially perpendicular to the major extension of the printed circuit board 40.

As FIG. 4 conveys, the hold-down device 52 has lateral detents 66 that encompass the positioning frame 56 on the underside. The side of the module 42 facing the printed circuit board 40 is referred to as the underside. Corresponding to these detents 66, the positioning frame 56 has ramp surfaces 68 on its upper side against which the detents 66 slide in the course of assembly when the hold-down device 52 is clipped to the positioning frame 56.

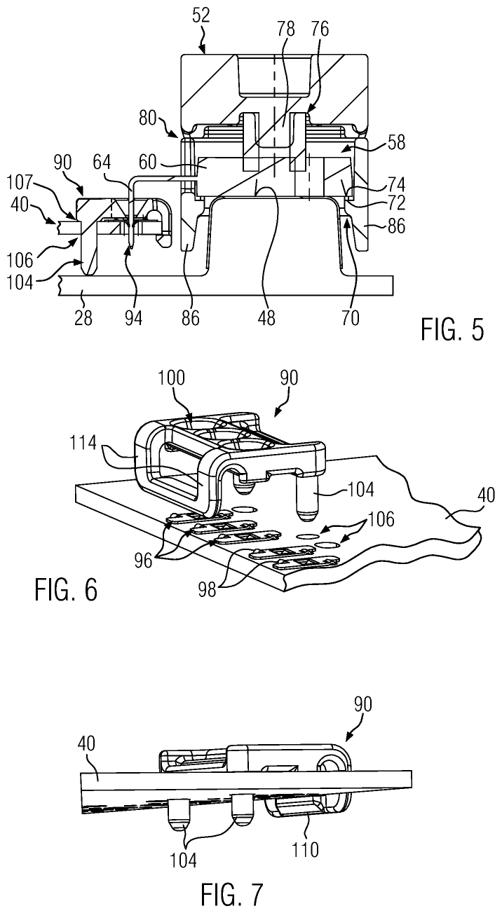

As can be seen from FIGS. 4 and 5, the accommodations 58 are substantially adapted to the dimensions of the power switches 60. On the underside, the positioning frame 56 forms an opening 70 in which the power switches 60 are each exposed. The opening 70 is bounded by a web 72 projecting toward the opening 70, which forms a support 74 for the power switch 60. FIGS. 4 and 5 furthermore show a spring device configured as a silicone spring 76 in the form of a hollow body. The silicone spring 76 is configured as a short piece of tubing and is pushed onto a pin 78 formed by the hold-down device 52, resulting in a form-fit connection between the silicone spring 76 and the hold-down device 52, via which the silicone spring 76 is fixed at right angles to its spring force relative to the hold-down device 52.

In the course of assembly, the individual components are first provided. Then the silicone spring 76 can be pushed onto the respective pins 78 in order to provide the hold-down device 52 with the spring devices. In parallel, the individual power switches 60 are inserted into the accommodations 58 assigned to them. For this purpose, the positioning frame 56 has a window, characterized by reference sign 80 in FIG. 5, which allows the power switch 60 to be lowered into the accommodation 58 without impairing the alignment of the contact pins 62. After the respective power switches 60 have been assembled, they rest on the support 74. The hold-down device 52 is then approached to the positioning frame 56. In the process, the detents 66 slide past the ramp surfaces 68. The detents 66 are spread and spring back on the underside of the positioning frame 56, forming a form-fit connection between the hold-down device 52 and the positioning frame 56. As part of this joining motion, the silicone springs 76 are accommodated between the hold-down device 52 and the power switches 60, slightly pretensioned if necessary. The module 42 thus produced is then assembled in the control housing 32. For this purpose, the module 42 is approached to the housing upper part 6. In the process, the cooling element 46 penetrates the opening 70 and is applied against the power switches 60 in a heat-conducting manner. An insulating layer, for example in the form of a polyimide film or a ceramic layer, is usually inserted beforehand between the cooling surface 48 and the power switches 60 to prevent direct electrical contact between the power switch 60 and the cooling element 46. The joining motion may be guided by the interaction of the form-fit segments 50 with the form-fit mating segments 54. This may result in pre-positioning of the module 42 relative to the cooling element 46.

Subsequently, screws characterized by reference sign 82 are screwed into the housing upper part 6. These have the effect of fixing the hold-down device 52 to the housing upper part 6 and thus compressing the silicone springs 76 and accordingly applying the power switches 60 under pretension. Obviously, the opening is appropriately dimensioned so that the cooling element 46 can easily immerse into the positioning frame 56. Cross beams 84 of the positioning frame 56, which bound the individual accommodations 58 in the longitudinal direction of the hold-down device 52 and separate the respective accommodations 58 from one another, allow a corresponding movement. These cross beams 84 are reduced in height compared to the longitudinal beams 86 drawn in FIG. 5.

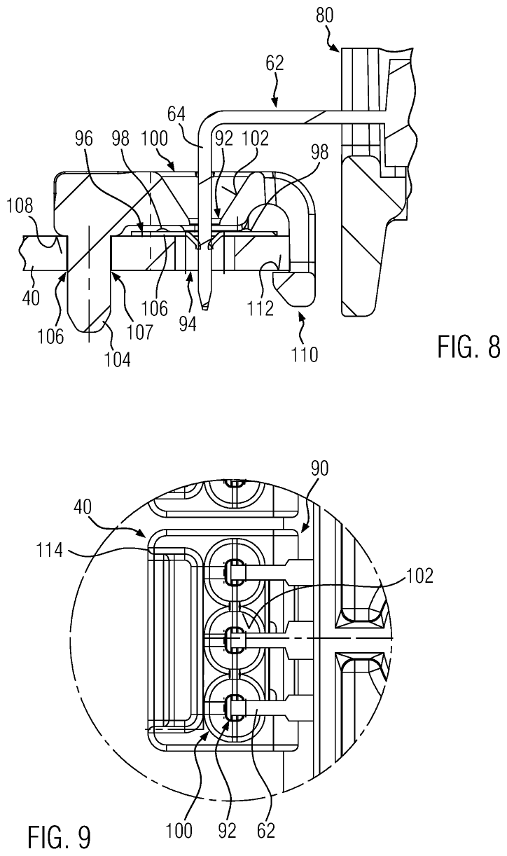

FIGS. 6 to 9 illustrate an alignment element of a plastic material characterized by reference sign 90 in FIG. 5. This serves to facilitate insertion of the contact-side section 64 of the contact pin into the printed circuit board 40. The alignment element 90 has a passage 92 which is aligned with a plug-in slot 94 for the respective contact pin 62 within the printed circuit board 40. The plug-in slot 94 is created by a connecting piece 96 which is electrically contacted with at least one strip conductor of the printed circuit board 40 and which is shown in FIGS. 6 and 8. The details of this connection are described in EP 2 236 330 A1 and counterpart U.S. Pat. No. 8,803,036, both of which are incorporated by reference. This connecting piece 96 lies basically flatly on the upper side of the printed circuit board 40. Only upwardly curved radii 98 of retaining webs which engage in bores of the printed circuit board 40 project slightly beyond the otherwise flat surface of the connecting pieces 96.

As can be seen in particular from FIGS. 8 and 9, the alignment element 90 has a significantly widened opening 100 around the passage 92 on the side facing away from the printed circuit board 40 compared to the dimensions of the passage 92. This opening 100 merges into the passage 92 without a shoulder via inwardly inclined ramp surfaces 102. The alignment element 90 is mounted on the printed circuit board 40 such that the passage 92 is precisely aligned with the plug-in slot 94 within the printed circuit board 40. For this purpose, the alignment element 90 comprises positioning pins 104 that extend through a positioning bore 106 within the printed circuit board 40 and project beyond the printed circuit board 40 on the underside. The positioning pins 104 extend from a protrusion that forms a contact surface 108, which is provided annularly around the positioning pin 104. The alignment element 90 is applied against the printed circuit board 40 via the contact surfaces 108. As can be seen from FIGS. 6 and 7, two positioning pins 104 and corresponding positioning bores are provided for each alignment element 90. Through this interaction, elements of a form-fit connection 107 are already provided by which the alignment element 90 is held transversely to the printed circuit board 40 in a form-fit manner and is fastened in this sense.

As can be seen in particular from FIGS. 6, 7, and 8, the alignment element 90 further has a latching leg 110 that forms a latching surface 112 abutting against the underside of the printed circuit board 40. This latching leg 110 also clips against the printed circuit board 40. The latching leg 110 is tethered by two connecting webs 114 that abut against the front surface of the printed circuit board 40 with a certain transverse spacing. By this configuration, the printed circuit board is encompassed at the edge by the alignment element 90.

As FIG. 5 illustrates, the free ends of the positioning pins 104 abut against the partition wall 28. In this way, the alignment element 90 is supported locally in the area of the passage 92, which mechanically relieves the printed circuit board 40 when the contact pins 62 are inserted.

As can be seen from FIG. 6, the alignment element 90 shown there has a plurality of passages 92 with corresponding openings 100 and ramp surfaces 102. The comparison of this illustration with FIG. 3 conveys that a single alignment element 90 is provided for each power switch 60. Thus, the number of passages 92 per alignment element 90 corresponds to the number of contact pins 62 of the power switch 60. FIG. 3 conveys four alignment elements 90 connected in series side by side with the printed circuit board 40.

In the course of assembling the module 42, the individual contact pins 62 with their contact-side sections 64 are aligned with the plug-in slots 94 via the respective ramp surfaces 102 of the corresponding alignment elements 90. Any misalignment is usually compensated for by the elasticity of the contact pins 62.

1. A control device for an electric heating device, the control device comprising:
a printed circuit board;
a control housing which surrounds the printed circuit board, which has a partition wall provided with a cooling element, and which accommodates at least one power switch that makes contact with the printed circuit board and that is applied in a heat-conducting manner against the cooling element via a hold-down device, wherein the power switch and the hold-down device are realized in a pre-assembled module connected to the cooling element.

2. The control device according to claim 1, wherein the module comprises a spring device which is provided between the hold-down device and the power switch and by which the power switch is applied under pretension against the cooling element.

3. The control device according to claim 2, wherein the spring device is held on the hold-down device via a form-fit connection acting at least transversely to a direction of action of its spring force.

4. The control device according to claim 2, wherein the spring device is formed by a silicone component.

5. The control device according to claim 4, wherein the silicone component comprises a hollow silicone body.

6. The control device according to claim 2, wherein the power switch is movably held in the module while varying a pretension is imposed by the spring device.

7. The control device according to claim 1, wherein the module comprises a positioning frame forming at least one accommodation for a respective power switch.

8. The control device according to claim 7, wherein the positioning frame and the hold-down device are clipped together with the power switch and the spring device.

9. The control device according to claim 7, wherein the positioning frame comprises an opening surrounding the cooling element and bounded by a support for the power switch.

10. The control device according to claim 7, wherein the positioning frame forms a window that is penetrated by at least one contact pin of the power switch and that is bounded at a top thereof by the hold-down device.

11. An electric heating device comprising:
a control device that includes
a printed circuit board, and
a control housing which surrounds the printed circuit board, which has a partition wall provided with a cooling element, and which accommodates at least one power switch that makes contact with the printed circuit board and that is applied in a heat-conducting manner against the cooling element via a hold-down device, wherein the power switch and the hold-down device are realized in a pre-assembled module connected to the cooling element;
a heater housing including a heating chamber, wherein the partition wall is provided between the control housing and the heater housing; and
at least one PTC heating assembly that protrudes from the partition wall as a heating fin into the heating chamber, wherein the PTC heating assembly has at least one PTC element and contact tongues which are electrically conductively connected to the PTC element with different polarity in order to energize the PTC element and which are electrically connected in the control housing;
wherein a heat sink to the cooling element is exposed in the heating chamber.

12. The electric heating device according to claim 11, wherein the module comprises a spring device which is provided between the hold-down device and the power switch and by which the power switch is applied under pretension against the cooling element.

13. The electric heating device according to claim 11, wherein the module comprises a positioning frame forming at least one accommodation for a respective power switch.

14. The electric heating device according to claim 13, wherein the positioning frame and the hold-down device are clipped together with the power switch and the spring device.
